(19) United States
(12) Patent Application Publication
(10) Pub. No.: US 2017/0212151 A1
(43) Pub. Date: Jul. 27, 2017

(54) CURRENT TRANSFORMER ASSEMBLY WITH ATTACHABLE FUNCTIONAL ADAPTOR

(71) Applicant: SELEC CONTROLS PVT. LTD., Navi Mumbai, Maharashtra (IN)

(72) Inventor: Samir KAJI, Navi Mumbai, Maharashtra (IN)

(73) Assignee: SELEC CONTROLS PVT. LTD., Navi Mumbai, Maharashtra (IN)

(21) Appl. No.: 15/328,864

(22) PCT Filed: Feb. 10, 2015
(86) PCT No.: PCT/IN2015/000077

§ 371 Date: Jan. 24, 2017

(30) Foreign Application Priority Data
Jul. 25, 2014 (IN) 2400/MUM/2014

(51) Int. Cl. G01R 15/18; G01R 19/00

(52) U.S. Cl. CPC G01R 15/18; G01R 19/0092

(57) ABSTRACT

A current transformer assembly for monitoring current flowing in an electrical circuit is disclosed. The assembly comprises a primary module (100) comprising at least one current transformer unit; and a secondary module (200) for processing an electrical signal; wherein, the primary module (100) and the secondary module (200) are functional independent from each other; and the secondary module (200) is adapted to be detachably, electrically connected to the primary module (100) for receiving at least one output electrical signal from the at least one current transformer unit of the primary module (100) to generate a processed output. The current transformer assembly is compact, and allows replacement or repair of either of the module, thereby giving cost-saving and commercial advantage.

### TECHNICAL FIELD OF INVENTION

The present invention relates to a current transformer device.

Particularly, the present invention relates to a current transformer assembly with attachable functional adaptor.

### BACKGROUND OF THE INVENTION

A current transformer is used for the measurement of electrical current in AC circuits. Commonly, they are used with measuring, controlling or protection devices for derivation of parameters like current, voltage, power factor, power, energy, etc. Typically a current transformer can be of the following types: a) Magnetic core-type having different sizes, shapes and construction, with electrical wire and insulation winding; b) Magnetic core-type having different sizes, shapes and construction, with hall-effect sensor assembly; and c) Air core with wire-in-coil form or known as Rogowski coil. These current transformers are built for single-phase and three-phase use. The current transformers can be further connected to one or more of the measuring, controlling and protection devices.

Very often the output signal of the current transformer needs further conditioning to be compatible with the required form of input signal that the measuring, controlling or protection device to which it is connected to is designed to receive. The conditioning components or device could include resistors or a combination circuit of active and passive components designed to produce required output. The conditioned output signal could be a millivolt signal, AC/DC signal conversion, or so-called instrumentation type signals, such as 0-10 volts, or 4-20 mAmp DC signals, or in digital form commonly known as ‘digitization’ of the signals. There are times when output of the transformer may require limiting, such as from over-current or over-voltage. Use of diodes, resistors, zener diodes, transistors, fuses or other passive or active devices, along with related circuits, are typically known to limit the output of the current transformer to levels which are safe for circuits in operation or to human life. Alternatively, protection devices may be used to prevent dangers of open secondary in the current transformer circuit, under hazardous condition. Further, a conversion device can be provided which gives conversion of the output signal from the current transformers in common terms of measurements like current, voltage, energy, power factor, power, frequency etc.

Commonly, one or more of these conditioning, limiting, measuring, protecting, and controlling devices are integrated in the current transformer assembly. U.S. Pat. No. 4,309,652 discloses one such current transformer circuit including a current developing means and an impedance means being operatively connected to each other to provide a current flow there through to substantially null voltages induced in a first secondary winding of the current transformer due to exciting currents present therein. U.S. Pat. No. 6,469,882 discloses another current transformer with initial condition correction. The current transformer assembly integrally comprises an analog to digital converter, and a controller for determining a trip condition. Further, U.S. Pat. No. 6,822,547 discloses a current transformer comprising a Rogowski coil which detects an alternating current of a main circuit of power distribution equipment or substation main circuits equipment, and outputs a measure of the alternating current as an analog-voltage signal, where the current transformer integrally comprises a sensor unit including an analog-to-digital converter which converts the analog-voltage signal into a digital electric signal, and an electric-to-optic converter which converts the digital electric signal into a digital optical signal.

In the known current transformer assemblies the auxiliary means are integrally-formed with the current transformer circuit. Therefore, the end user does not have the flexibility to chose or vary function of the current transformer. This limits the application or use of the current transformer to a particular device or main circuit. Also, in case of a functional error requiring maintenance or repair, the current transformer device must be returned to the manufacturer/dealer for repair or replacement, with no option for a quick-fix solution at the user end. There is therefore felt a need for a current transformer device which can be customized as per the final application, and which will overcome the afore-listed drawbacks of the known current transformer assemblies.

### SUMMARY OF THE INVENTION

It is an object of the present invention to provide a modular, adaptable current transformer assembly, in which, a first module comprises a current transformer, and a second module comprises one or more auxiliary means selected from a conditioning, limiting, measuring, protecting, controlling and communicating means, such that each module is attachable in a seamless and modular fashion to provide enhanced efficiency.

It is another object of the present invention to provide a modular current transformer assembly in which the first module and the second module when unassembled are adapted to function individually, thus allowing replacement or repair of either of the module, thereby giving cost-saving and commercial advantage.

It is still another object of the present invention to provide a modular current transformer assembly which is compact, and which can be assembled by the end user.

It is yet another object of the present invention to provide a modular current transformer assembly in which the current transformer is attached to the onward functional means, and does not require external current transformer signals wiring and mounting of the functional device elsewhere.

It is a further object of the present invention to provide a modular current transformer assembly whose functionality may be varied depending upon the end use by simply altering the second module.

It is an additional object of the present invention to provide a modular current transformer assembly which can be remotely communicated to increase reach of the interconnections thereof.

These objects and other advantages of the present invention will be more apparent from the following description of the preferred embodiments of the present invention.

Accordingly, the present invention discloses a current transformer assembly, said assembly including:
a primary module comprising at least one current transformer unit for monitoring current flowing in an electrical circuit to generate at least one output electrical signal; and
a secondary module for processing an electrical signal;
wherein,
said primary module and said secondary module are functional independent from each other; and
said secondary module is adapted to be detachably, electrically connected to said primary module for receiving said at least one output electrical signal from said at least one current transformer unit of said primary module to generate a processed output, such that when connected said primary module and said secondary module function as a single device.

Typically, the primary module of the present invention comprises at least one interconnection means, said at least one interconnection means may be one or more means selected from terminal, connector, transmitter, control and communication means.

Preferably, the secondary module of the present invention comprises at least one means selected from conditioning means, limiting means, measuring means, protecting means, controlling means and communication means. The secondary module of the present invention comprises an input means and an output means, said input means and said output means may be one or more means selected from terminal, connector, transmitter, display, control, and communication means. More preferably, the primary module of the present invention comprises at least one interconnection means being adapted for receiving said input means of said secondary module.

Preferably, said primary module and said secondary module are attached by at least one mechanism selected from snap-fitting, fastening, locking, interlocking, guiding, and joining.

The primary module and said secondary module of the present invention may further comprise one or more accessories selected from mounting means, tamper-proofing means, safety means, and environment-protection means.

The current transformer assembly of the present invention may further comprise an input module comprising at least one device selected from functional adaptor, extension and plug, being adapted for receiving at least one external device selected from circuit breaker, relay, and bus bar; said input module being detachably attached to said primary module by at least one mechanism selected from snap-fitting, fastening, locking, interlocking, guiding, and joining.

The current transformer assembly of the present invention may be designed for single-phase or multi-phase electrical circuits.

The current transformer assembly of the present invention may be designed for residual-current or differential-current systems.

### BRIEF DESCRIPTION OF THE ACCOMPANYING DRAWINGS

The present invention will be described here below with reference to the following drawings, in which,

FIG. 1A & 1B illustrate a perspective view of a preferred embodiment of the current transformer assembly showing a primary module 100 and a secondary module 200, in accordance with the present invention;

FIG. 2 illustrates a partial exploded view of the preferred embodiment of the current transformer assembly in accordance with the present invention;

FIG. 3 illustrates a partial exploded view of the secondary module 200 of the preferred embodiment of the current transformer assembly in accordance with the present invention;

FIG. 4 illustrates a perspective view of another preferred embodiment of the current transformer assembly having split core-type current transformer, in accordance with the present invention; and

FIG. 5 illustrates a perspective view of yet another preferred embodiment of the current transformer assembly in accordance with the present invention.

### DETAILED DESCRIPTION OF THE INVENTION

The embodiments herein and the various features and advantageous details thereof are explained with reference to the non-limiting examples in the following description. The examples used herein are intended merely to facilitate an understanding of the ways in which the embodiments herein may be practiced and to further enable those of skill in the art to practice the embodiments herein. Accordingly, the examples should not be construed as limiting the scope of the embodiments herein.

The description herein after, of the specific embodiments will so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein can be practiced with modification within the spirit and scope of the embodiments as described herein

The present invention envisages a modular, adaptable current transformer assembly comprising two distinct modules, viz., a primary module and a secondary module. The current transformer assembly is adapted for monitoring current flow in a single-phase or a multi-phase electrical circuit, or for a residual-current system or differential-current system. The secondary module is an auxiliary means for conditioning, limiting, measuring, protecting, controlling and communicating, the primary module or its output signal thereof. The primary module and the secondary module are adapted to function independently, thus giving opportunity for maintenance, replacement or repair of either of the module at a given time, thereby providing a cost-saving in operation as well as manufacturing. Also, allowing the end user to adapt the current transformer assembly as per the final application and requirements, or alter a given assembly as per need. The novel design is compact, and can be assembled or disassembled by the end user, enhancing the usability of the device. In the modular current transformer assembly, in which the current transformer is attached to the onward functional means, does not require external current transformer signals wiring and mounting of the functional device elsewhere. The current transformer assembly of the present invention can be adapted to different applications like simple current sensor, or applied to a device to be used in combination for energy monitoring, earth fault, or earth leakage as protection, etc; which adaptation can be done for any current transformer type and for single or multiple current transformers. As the modules are distinct and can function independently, the present invention may be provided with remote communication or connection to enhance reach of the interconnections thereof, where the modules may comprise inbuilt wired or wireless communications. The assembly of the present invention provides provision for designing the individual modules with need-based electrical and/or electronic sub-assembly.

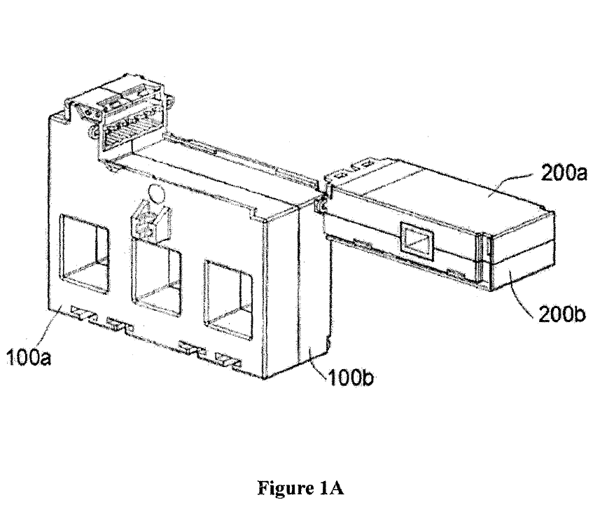

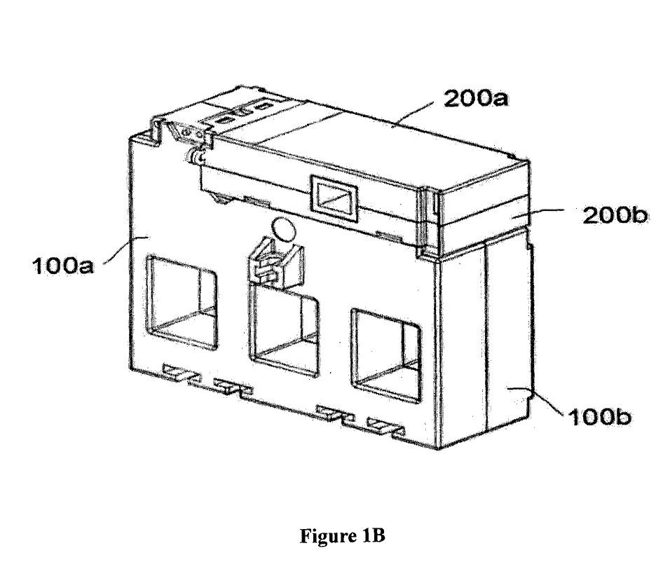

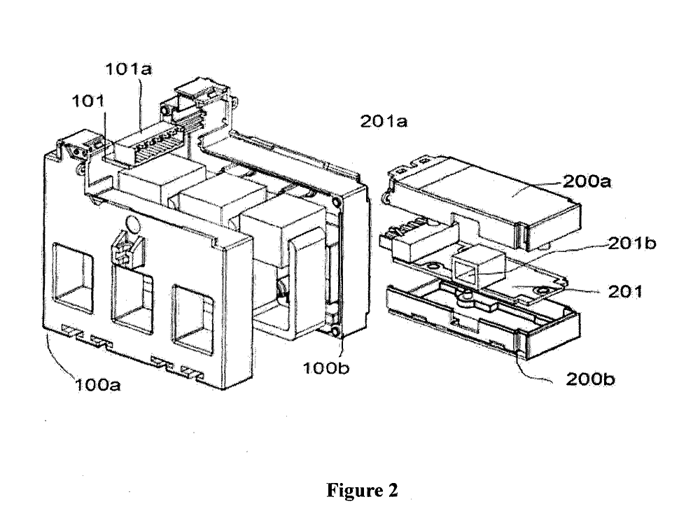

Referring to FIGS. 1A, 1B, 2, & 3 of the accompanying drawings, therein is disclosed a preferred embodiment of the current transformer assembly of the present invention. The current transformer assembly comprises a primary module 100. The primary module 100 comprises at least one current transformer unit for monitoring the current flow through the electrical circuit. A first primary module portion 100a and a second primary module portion 100b define the housing of the primary module 100. The first primary module portion 100a and the second primary module portion 100b may be attached by means of a mechanism selected from snap-fitting, fastening, locking, interlocking, guiding, and joining/welding.

An exploded view of the primary module 100 is illustrated in the FIG. 2. In a preferred embodiment, the at least one current transformer unit can be a magnetic core-type current transformer with electrical wire and insulation winding, a magnetic core-type current transformer with hall-effect sensor assembly, and/or air core-type current transformer with Rogowski coil. The current transformer can have various sizes, shapes, and construction. The primary module 100 comprises at least one interconnection means 101a, as illustrated in the FIG. 2. The interconnection means 101a are supported by connecting means 101, shown in FIG. 2. The connecting means 101 may include a printed circuit board. The interconnection means 101a can be one or more means selected from terminal, connector, transmitter, control and communication means. The communication means may provide wired or wireless communication or optical communication. The interconnection means 101a may comprise display means such as a LCD or LED screen, touch screen, control knobs, keys, connectors, and the like. The primary module 100 may comprise accessories like mounting means, tamper-proofing means, safety means, and environment-protection means.

The secondary module 200 is adapted to function independently from the primary module 100. In correlation, the secondary module 200 is received at the interconnection means 101a of the primary module 100 such as to be detachably and electrically connected to the at least one current transformer unit of the primary module 100, such that when attached the primary module 100 and the secondary module 200 function as a single device. A first secondary module portion 200a and a second secondary module portion 200b define the housing of the secondary module 200. The first secondary module portion 200a and the second secondary module portion 200b may be attached by means of a mechanism selected from snap-fitting, fastening, locking, interlocking, guiding, and joining/welding. The secondary module 200 comprises a functional part 201, an input means 201a and an output means 201b. The input means 201a and the output means 201b may be one or more means selected from terminal, connector, transmitter, display, control, and communication means. The communication means may provide wired or wireless communication or optical communication. The input means 201a and the output means 201b may comprise display means such as a LCD or LED screen, touch screen, control knobs, keys, connectors, and the like. In operation, the input means 201a are adapted to be connected to the interconnection means 101a to receive an output electrical signal from the at least one current transformer unit of the primary module 100. The secondary module 200 process the electrical signal. The secondary module 200 may comprise one or more of the means selected from conditioning means, limiting means, measuring means, protecting means, controlling means and communication means. The secondary means 200 receive the output electrical signal from the primary module 100 and process it to provide a processed electrical output. Alternatively, the secondary module 200 may control or protect the primary module 100 or display the output signal thereof. The secondary module 200 may comprise accessories like mounting means, tamper-proofing means, safety means, and environment-protection means. The location of the input means 201a is flexible and is dependent on the interconnection means 101a. The processed output is obtained at the output means 201b. The location of the output means 201b is flexible.

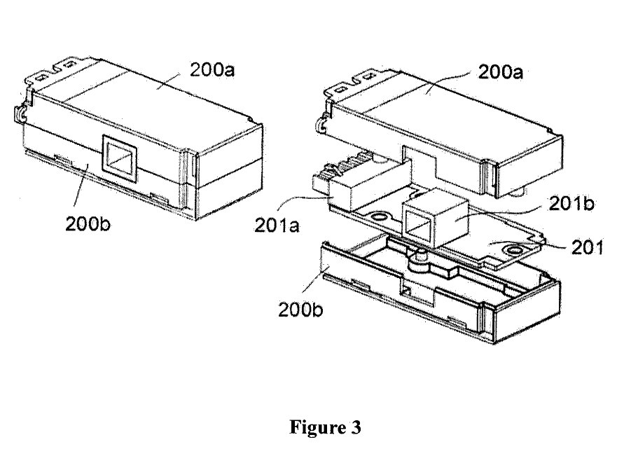

FIG. 1A shows the separate units of the primary module 100 and the secondary module 200, while FIG. 1B shows the assembly of the primary module 100 and the secondary module 200. FIG. 2 shows an exploded view of the primary module 100 showing the connecting means 101 and the interconnection means 101a. FIG. 3 illustrates an exploded view of the secondary module 200 showing the functional part 201, an input means 201a and an output means 201b.

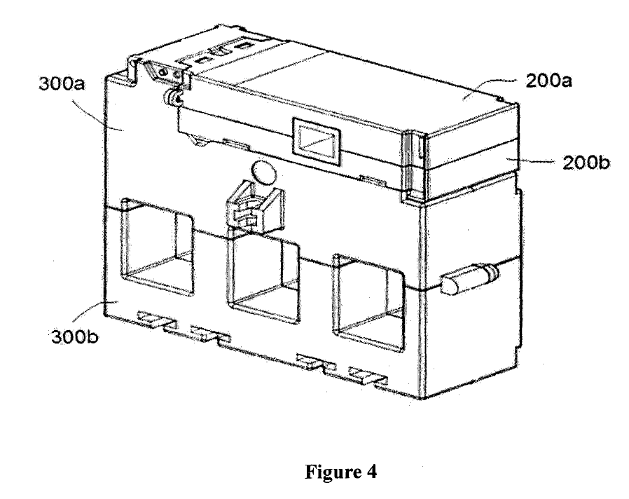

FIG. 4 of the accompanying drawings illustrates another preferred embodiment of the current transformer assembly of the present invention, comprising a primary module 300 adapted to include at least one split core-type current transformer unit. The arrangement of the first primary module portion 300a and the second primary module portion 300b is illustrated in the FIG. 4.

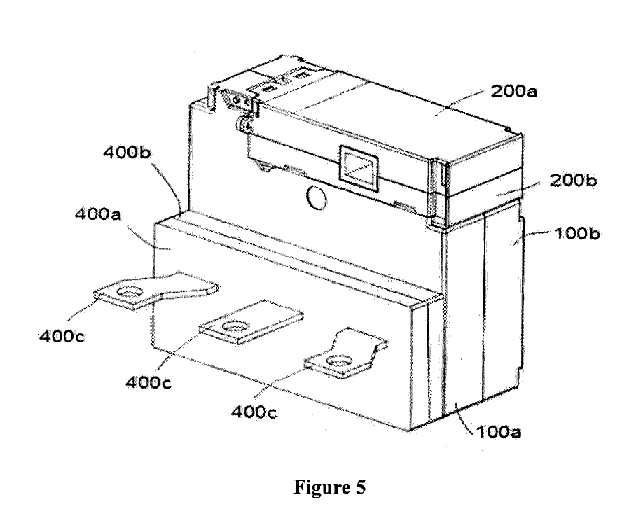

FIG. 5 of the accompanying drawings illustrates yet another preferred embodiment of the current transformer assembly of the present invention. The current transformer assembly is provided with an input module 400. The input module 400 is at least one device selected from a functional adaptor, an extension and a plug. The input module 400 is further adapted to receive at least one external device selected from a circuit breaker, a relay, and a bus bar. The input module 400 is detachably attached to the primary module 100 by at least one mechanism selected from snap-fitting, fastening, locking, interlocking, guiding, and joining. The input module 400 is electrically attached at the input of the primary module 100. The input module 400 can also be provided with the embodiment of FIG. 4. The input module 400 may comprise accessories like mounting means, tamper-proofing means, safety means, and environment-protection means. The input module 400 comprises a first input module portion 400a, a second input module portion 400b. The first input module portion 400a and the second input module portion 400b may be attached by means of a mechanism selected from snap-fitting, fastening, locking, interlocking, guiding, and joining/welding. The first input module portion 400a and the second input module portion 400b define the housing of the input module. The input module 400 comprises connecting elements 400c having various sizes and configurations and made of different components like spader for standard MCCB, copper or brass connectors, custom lugs, barrier elements in between spaders or copper, brass connectors, with or without internal potting or insulating means or external elements made up of insulating material which can be separately mounted on portions 400a & 400b. The input module 400 can be provided with any of the preferred embodiments of the present invention illustrated in the FIGS. 1, 2 & 4.

Any discussion of documents, acts, materials, devices, articles or the like that has been included in this specification is solely for the purpose of providing a context for the invention. It is not to be taken as an admission that any or all of these matters form part of the prior art base or were common general knowledge in the field relevant to the invention as it existed anywhere before the priority date of this application.

Embodiment of the present invention is applicable over a wide number of uses and other embodiments may be developed beyond the embodiment discussed heretofore. Only the most preferred embodiments and their uses have been described herein for purpose of example, illustrating the advantages over the prior art obtained through the present invention; the invention is not limited to these specific embodiments or their specified uses. Thus, the forms of the invention described herein are to be taken as illustrative only and other embodiments may be selected without departing from the scope of the present invention. It should also be understood that additional changes and modifications, within the scope of the invention, will be apparent to one skilled in the art and that various modifications to the construction described herein may fall within the scope of the invention.

1. A current transformer assembly, said assembly including:
a primary module (100) comprising at least one current transformer unit for monitoring current flowing in an electrical circuit to generate at least one output electrical signal; and
a secondary module (200) for processing an electrical signal;
wherein,
said primary module (100) and said secondary module (200) are functional independent from each other; and
said secondary module (200) is adapted to be detachably, electrically connected to said primary module (100) for receiving said at least one output electrical signal from said at least one current transformer unit of said primary module (100) to generate a processed output, such that when connected said primary module (100) and said secondary module (200) function as a single device.

2. The current transformer assembly as claimed in claim 1, wherein said primary module (100) comprises at least one interconnection means (101a), said at least one interconnection means (101a) are one or more means selected from terminal, connector, transmitter, control and communication means.

3. The current transformer assembly as claimed in claim 1, wherein said secondary module (200) comprises at least one means selected from conditioning means, limiting means, measuring means, protecting means, controlling means and communication means.

4. The current transformer assembly as claimed in claim 1, wherein said secondary module (200) comprises an input means (201a) and an output means (201b), said input means (201a) and said output means (201b) are one or more means selected from terminal, connector, transmitter, display, control, and communication means.

5. The current transformer assembly as claimed in claim 4, wherein said primary module (100) comprises at least one interconnection means (101a) being adapted for receiving said input means (201a) of said secondary module (200).

6. The current transformer assembly as claimed in claim 1, wherein said primary module (100) and said secondary module (200) are attached by at least one mechanism selected from snap-fitting, fastening, locking, interlocking, guiding, and joining.

7. The current transformer assembly as claimed in claim 1, wherein said primary module (100) and said secondary module (200) further comprise one or more accessories selected from mounting means, tamper-proofing means, safety means, and environment-protection means.

8. The current transformer assembly as claimed in claim 1, wherein said assembly further comprises an input module (400) comprising at least one device selected from functional adaptor, extension and plug, being adapted for receiving at least one external device selected from circuit breaker, relay, and bus bar; said input module (400) being detachably attached to said primary module (100) by at least one mechanism selected from snap-fitting, fastening, locking, interlocking, guiding, and joining.

9. The current transformer assembly as claimed in claim 1, wherein said current transformer assembly is designed for single-phase or multi-phase electrical circuits.

10. The current transformer assembly as claimed in claim 1, wherein said current transformer assembly is designed for residual-current or differential-current systems.
